(19) United States
(12) Patent Application Publication
(10) Pub. No.: US 2026/0059743 A1
(43) Pub. Date: Feb. 26, 2026

(54) SEMICONDUCTOR MEMORY STRUCTURE AND METHOD FOR FORMING THE SAME

(71) Applicant: Winbond Electronics Corp., Taichung City (TW)

(72) Inventors: Hsuan-Tung CHU, Tainan City (TW); Shuo-Ting YU, Tainan City (TW)

(21) Appl. No.: 19/300,118

(22) Filed: Aug. 14, 2025

(30) Foreign Application Priority Data
Aug. 21, 2024 (TW) 113131439

(51) Int. Cl. H10B 12/00; H01L 21/762; H01L 21/768

(52) U.S. Cl. CPC H10B 12/482; H01L 21/76232; H01L 21/76843

(57) ABSTRACT

A semiconductor memory structure includes a first active region and a second active region adjacent to the first active region, an isolation structure surrounding the first active region and the second active region, a first bit line structure extending across the first active region, and a contact plug extending into the second active region. The isolation structure includes a first insulating material and a second insulating material disposed on the first insulating material. The first bit line structure includes a contact portion extending into the first active region. An upper surface of the first insulating material is positioned lower than a bottom of the contact portion.

### CROSS REFERENCE TO RELATED APPLICATIONS

This application claims the benefit of Taiwan Patent Application No. 113131439 filed on Aug. 21, 2024, entitled “SEMICONDUCTOR MEMORY STRUCTURE AND METHOD FOR FORMING THE SAME” which is hereby incorporated herein by reference.

### BACKGROUND

### Field of the Disclosure

The present disclosure relates in general to a semiconductor memory structure and a method for forming the same, and in particular, it relates to dynamic random access memory and a method for forming the same.

### Description of the Related Art

In order to increase the component density within Dynamic Random Access Memory (DRAM) devices and enhance their overall performance, current manufacturing techniques for DRAM devices are continually striving towards miniaturization of components through a reduction in their overall size. Therefore, improving the methods of manufacturing DRAM devices is a crucial challenge that must be addressed.

### SUMMARY

A semiconductor memory structure includes a first active region, a second active region, an isolation structure, a first bit line structure, and a contact plug. The second active region is adjacent to the first active region. The isolation structure surrounds the first active region and the second active region. The first bit line structure extends across the first active region. The contact plug extends into the second active region. The isolation structure includes a first insulating material and a second insulating material. The second insulating material is disposed on the first insulating material. The first bit line structure includes a contact portion that extends into the first active region. An upper surface of the first insulating material is positioned lower than a bottom of the contact portion.

The method of forming a semiconductor memory structure includes patterning a semiconductor substrate to form a first active region and a second active region. The method includes depositing a first insulating material to surround the first active region and the second active region. The method includes recessing the first insulating material. The method includes depositing a second insulating material over the first insulating material to surround an upper portion of the first active region and an upper portion of the second active region. The method includes etching the first active region and the second insulating material to form a first opening. The method includes forming a bit line structure extending across the first active region and partially filling the first opening. The method includes etching the second active region and the second insulating material to form a second opening. The method includes depositing a conductive material into the second opening.

### BRIEF DESCRIPTION OF THE DRAWINGS

In accordance with some embodiments of the present disclosure, it may be further understood by reading the subsequent detailed description and examples with references made to the accompanying drawings, wherein:

FIGS. 1A, 7A, 9A, 10A, 11A and 12A are top views illustrating the formation of a semiconductor memory structure at various immediate stages, in accordance with some embodiments.

FIGS. 1B, 2, 3, 4, 5, 6, 7B, 8, 9B, 10B, 11B and 12B are cross-sectional views illustrating the formation of a semiconductor memory structure at various intermediate stages, in accordance with some embodiments.

FIGS. 11C and 12C are enlarged views of FIGS. 11B and 12B, in accordance with some embodiments.

FIGS. 13A and 13B are a modification of the semiconductor memory structure of FIGS. 12B and 12C, in accordance with some embodiments.

FIGS. 14A and 14B are a modification of the semiconductor memory structure of FIGS. 12B and 12C, in accordance with some embodiments.

### DETAILED DESCRIPTION

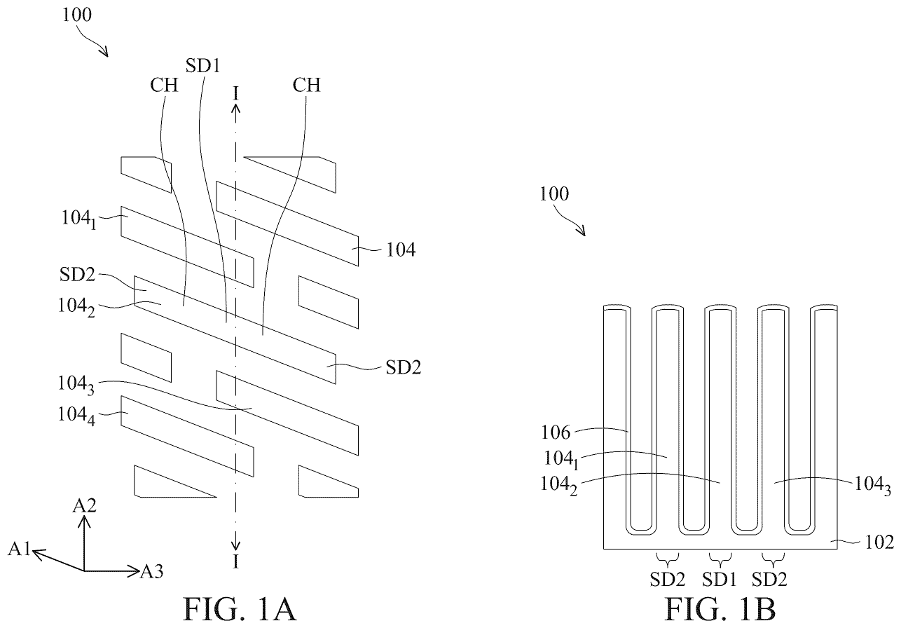

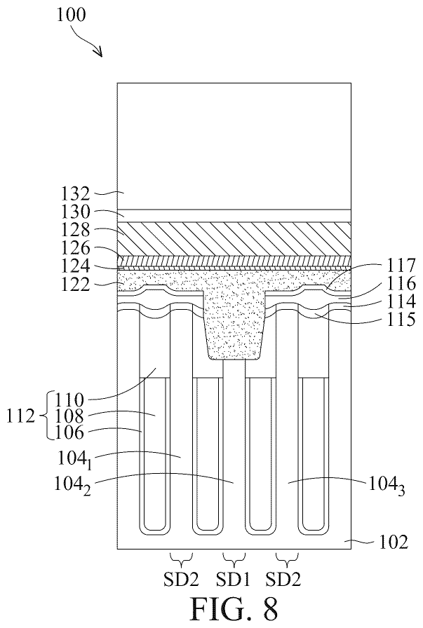

FIGS. 1A, 7A, 9A, 10A, 11A, and 12A are top views illustrating the formation of a semiconductor memory structure 100 at various immediate stages according to some embodiments of the present invention. FIGS. 1B, 2, 3, 4, 5, 6, 7B, 8, 9B, 10B, 11B, and 12B are cross-sectional views illustrating the formation of the semiconductor memory structure 100 at various immediate stages. These cross-sectional views correspond to cross-section I-I in the top views.

The directions A1, A2, and A3 shown in the top views are horizontal directions, where the first direction A1 is the channel extension direction, the second direction A2 is the word line extension direction, and the third direction A3 is the bit line extension direction. The first direction A1 intersects the second direction A2 at an acute angle, which ranges, for example, from about 10 degrees to about 80 degrees. The second direction A2 is substantially perpendicular to the third direction A3.

Referring to FIGS. 1A and 1B, a plurality of active regions 104 are formed over a substrate 102. In some embodiments, the semiconductor substrate 102 is an elemental semiconductor substrate, such as a silicon substrate or a germanium substrate, or a compound semiconductor substrate, such as a silicon carbide substrate or a gallium arsenide substrate. In some embodiments, the semiconductor substrate 102 may be a semiconductor-on-insulator (SOI) substrate.

The active regions 104 are semiconductor islands extending along the first direction A1. Each active region 104 may include or is defined as a first source/drain region SD1 at the center of the semiconductor island, two second source/drain regions SD2 at opposite ends of the semiconductor island, and two channel regions CH between the first source/drain region SD1 and the second source/drain regions SD2.

The formation of the active regions 104 may include performing a first patterning process on the semiconductor substrate 102 to form semiconductor strips extending in the first direction A1, followed by a second patterning process to cut each semiconductor strip into multiple separated semiconductor islands. The first and second patterning processes may include a photolithography process and an etching process.

Along the second direction A2, the positions of adjacent active regions 104 are staggered. The active regions 104 may be periodically aligned. For example, along the second direction A2, the active region 104₁ is aligned with the active region 104₄, with the active regions 104₂ and 104₃ interposed between them. The cross-section I-I is a plane parallel to the second direction A2 and passes through the second source/drain region SD2 of the active region 104₁, the first source/drain region SD1 of active region 104₂, and the second source/drain region SD2 of active region 104₃.

A liner 106 is formed along the active regions 104, as shown in FIG. 1B. The liner 106 may be made of silicon oxide, which may be formed using in-situ steam generation (ISSG), chemical vapor deposition (CVD), and/or atomic layer deposition (ALD).

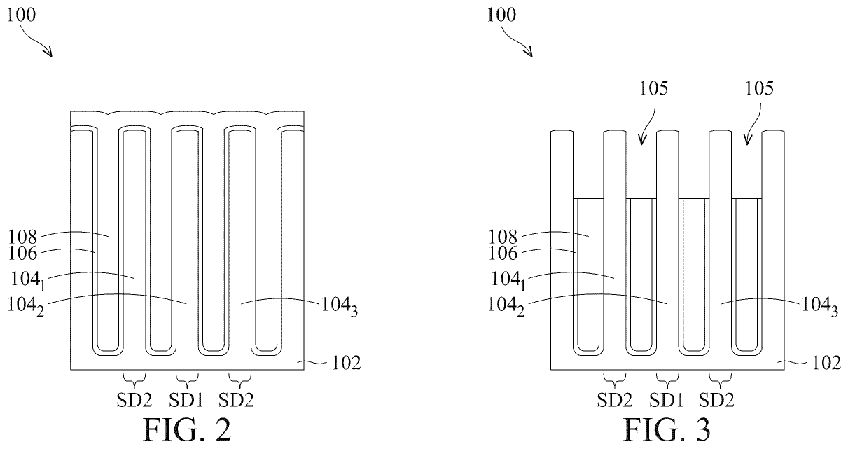

A first insulating material 108 is formed over the liner 106 and overfills the trenches between the active regions 104, as shown in FIG. 2. In some embodiments, the first insulating material 108 is made of a dielectric material, such as silicon oxide (SiO), silicon nitride (SiN), silicon oxynitride (SiON), other suitable materials, and/or combinations thereof. The first insulating material 108 may be deposited using chemical vapor deposition and/or atomic layer deposition.

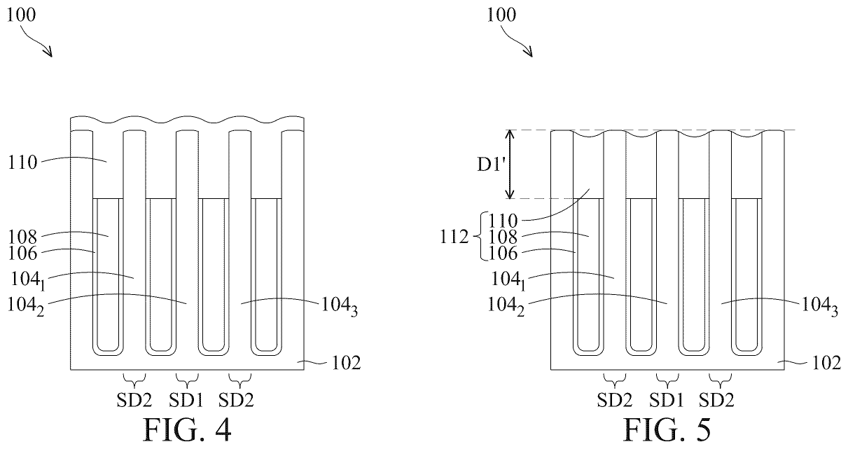

An etching process is performed on the semiconductor memory structure 100 to recess the liner 106 and the first insulating material 108, thereby forming trenches 105, as shown in FIG. 3. The etching process may be a wet etching process or a dry etching process.

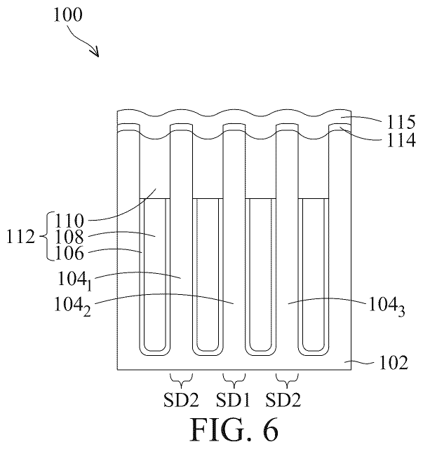

A second insulating material 110 is formed over the liner 106, the first insulating material 108, and the active regions 104, and overfills the trenches 105, as shown in FIG. 4. In some embodiments, the second insulating material 110 is formed of a dielectric material, such as silicon nitride (SiN), silicon oxynitride (SiON), silicon oxide (SiO), other suitable materials, and/or combinations thereof. The second insulating material 110 may be deposited using chemical vapor deposition and/or atomic layer deposition. The second insulating material 110 has a different etching selectivity than that of the first insulating material 108 and the active regions 104. In one embodiment, the first insulating material 108 is an oxide layer such as a silicon oxide layer, the second insulating material 110 is a nitride layer such as silicon nitride layer, and the active regions 104 are made of silicon.

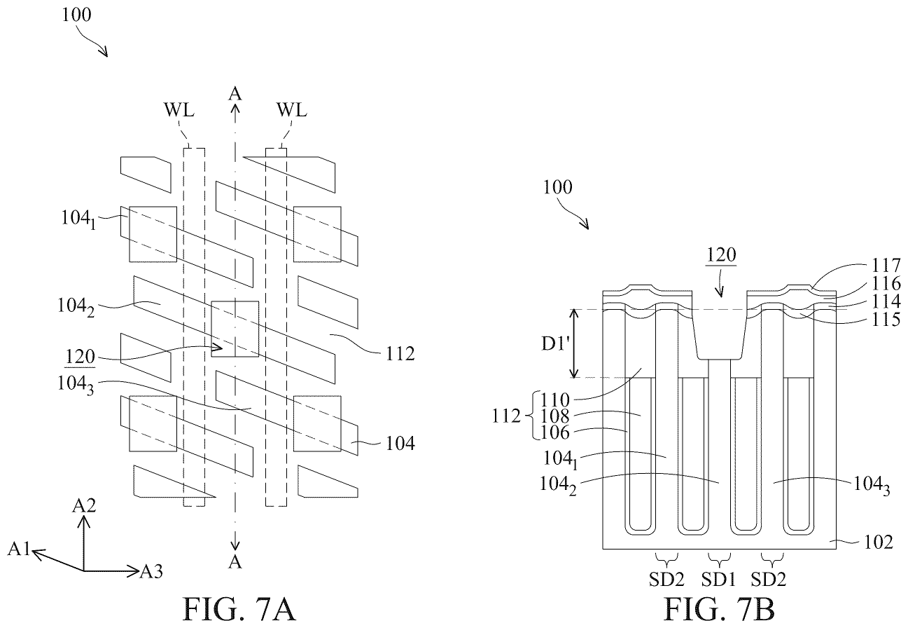

An etching process is performed on the semiconductor memory structure 100 to recess the second insulating material 110 until the tops of the active regions 104 is exposed, as shown in FIG. 5. The etching process may be a wet etching process or a dry etching process. The dimension D1′ of the recessed second insulating material 110, measured from the top of the active region 104, is within a range of about 50 nm to about 200 nm. The liner 106 and the first insulating material 108 collectively surround the lower portions of the active regions 104, while the second insulating material 110 surrounds the upper portions of the active regions 104. The liner 106, the first insulating material 108, and the second insulating material 110 together form an isolation structure 112.

A liner 114 is formed along the exposed tops of the active regions 104. The liner 114 may be an oxide layer formed by an in-situ steam generation (ISSG) process. Subsequently, a dielectric layer 115 is formed over the semiconductor memory structure 100. In some embodiments, the dielectric layer 115 is made of a dielectric material such as silicon oxide (SiO), silicon nitride (SiN), silicon oxynitride (SiON), other suitable materials, and/or combinations thereof. The dielectric layer 115 may be deposited by chemical vapor deposition (CVD) and/or atomic layer deposition (ALD).

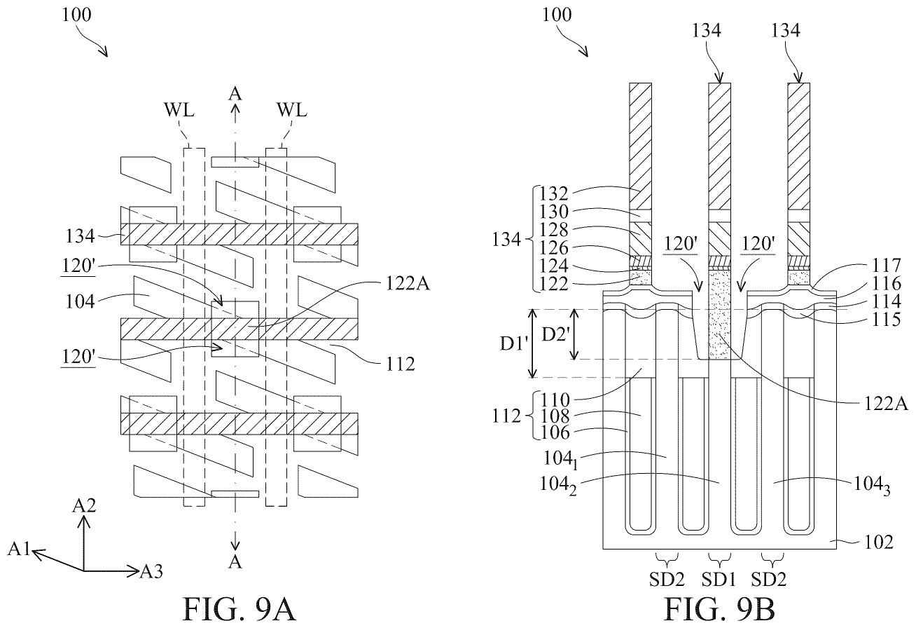

Referring to FIG. 7A, word lines WL are formed along the second direction A2 and pass through the channel regions CH of the active regions 104. The word lines WL are also referred to as buried word lines. Each active region 104 may be intersected by two word lines WL. Although not explicitly shown, the word lines WL may include a gate dielectric layer and a gate electrode layer. The formation of the word lines WL may include patterning the semiconductor memory structure 100 to form trenches, depositing materials for the gate dielectric layer and gate electrode layer, and removing excess gate material over the active regions 104.

During the formation of the word lines WL, a portion of the dielectric layer 115 over the liner 114 is removed, and mask layers 116 and 117 are formed. The mask layer 116 may be a silicon nitride layer, while the mask layer 117 may be a silicon oxide layer.

A patterning process is performed on the semiconductor memory structure 100 to form first openings 120, as shown in FIGS. 7A and 7B. Each first opening 120 corresponds to a first source/drain region SD1 and overlaps the adjacent isolation structure 112. The patterning process may include a lithography process and an etching process (e.g., a wet etching process or a dry etching process). During the etching process, the first source/drain regions SD1 of the active regions 104 (e.g., the active region 104₂ in FIG. 7B) and the adjacent second insulating material 110 are recessed to form the first openings 120.

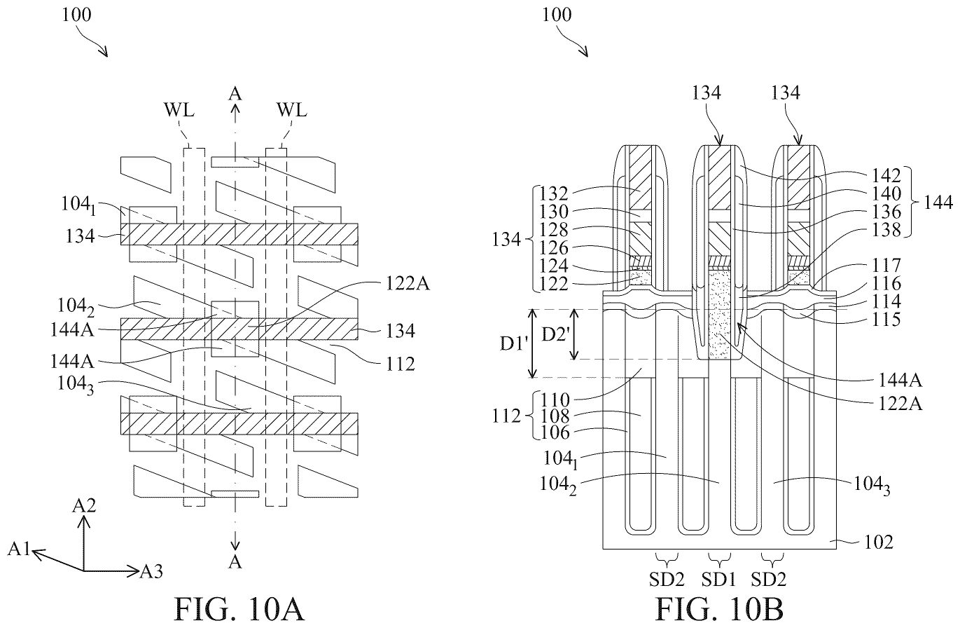

A first conductive layer 122, a silicide layer 124, a second conductive layer 126, a third conductive layer 128, a mask layer 130, and a mask layer 132 are sequentially formed, as shown in FIG. 8. The first conductive layer 122 overfills the first openings 120. The first conductive layer 122 is made of doped or undoped polysilicon. The silicide layer 124 is made of titanium silicide (TiSi), cobalt silicide (CoSi), nickel silicide (NiSi), or other suitable materials. The second conductive layer 126 is made of a barrier material such as a metal nitride (e.g., titanium nitride (TiN) or tantalum nitride (TaN)). The third conductive layer 128 is made of a metal material such as tungsten (W), aluminum (Al), copper (Cu), cobalt (Co), or ruthenium (Ru). The mask layers 130 and 132 are formed of dielectric materials such as silicon nitride (SiN), silicon oxynitride (SiON), and/or silicon oxide (SiO). These materials may be deposited by a deposition process.

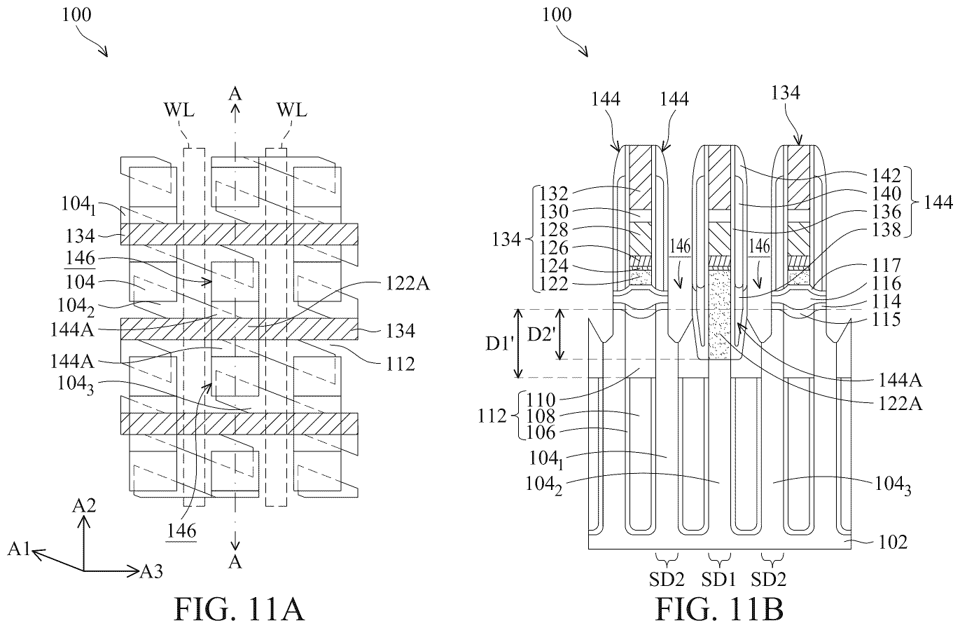

A patterning process is performed on the mask layers 132 and 130, the third conductive layer 128, the second conductive layer 126, the silicide layer 124, and the first conductive layer 122 to form bit line structures 134, as shown in FIGS. 9A and 9B. The patterning process may include a lithography process and an etching process (e.g., a wet etching process or a dry etching process). The bit line structures 134 extend along the third direction A3 and across the active regions 104 and the isolation structure 112. The portion of the first conductive layer 122 in the first openings 120 (FIG. 7B) serves as contact portions 122A of the bit line structures 134. The contact portions 122A are located on the first source/drain regions SD1 of the active regions 104 (e.g., active region 104₂ in FIG. 9B).

The patterning process partially removes the first conductive layer 122 in the first openings 120, thereby forming openings 120′ on the opposite sides of the contact portions 122A. The bottom of the contact portion 122A is positioned higher than the interface between the second insulating material 110 and the first insulating material 108. The dimension D2′, vertically measured from the top of the active region 104 to the bottom of the contact portion 122A, is within a range of about 25 nm to about 45 nm.

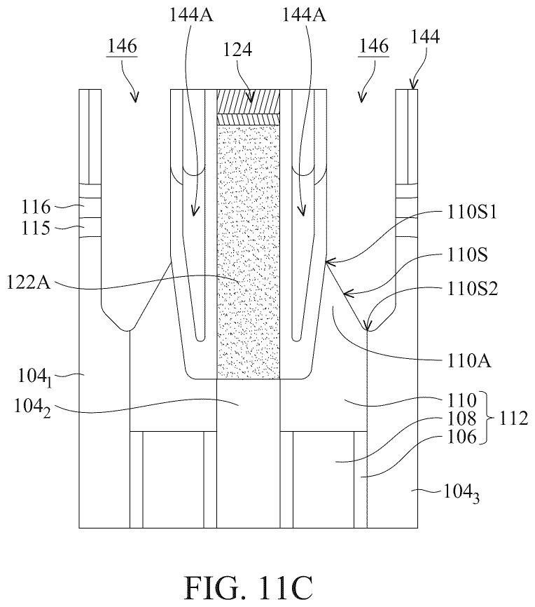

Spacer structures 144 are formed on opposite sides of the bit line structures 134, as shown in FIG. 10B. The spacer structures extend along the third direction A3 and across the active regions 104 and the isolation structure 112. The spacer structure 144 includes a first spacer layer 136, a second spacer layer 138, a third spacer layer 140, and a fourth spacer layer 142. The first spacer layer 136, the second spacer layer 138, and the fourth spacer layer 142 may be made of silicon oxynitride, silicon nitride, or carbon silicon oxide, while the third spacer layer 140 may be made of silicon oxide. The spacer structures 144 may be formed by depositing these spacer materials followed by one or more etching processes. The extending portions of the spacer structures 144 filling the openings 120′ are labeled as 144A, as shown in FIGS. 10A and 10B. The extending portions 144A of the spacer structures 144 are formed from the first spacer layer 136 and the second spacer layer 138.

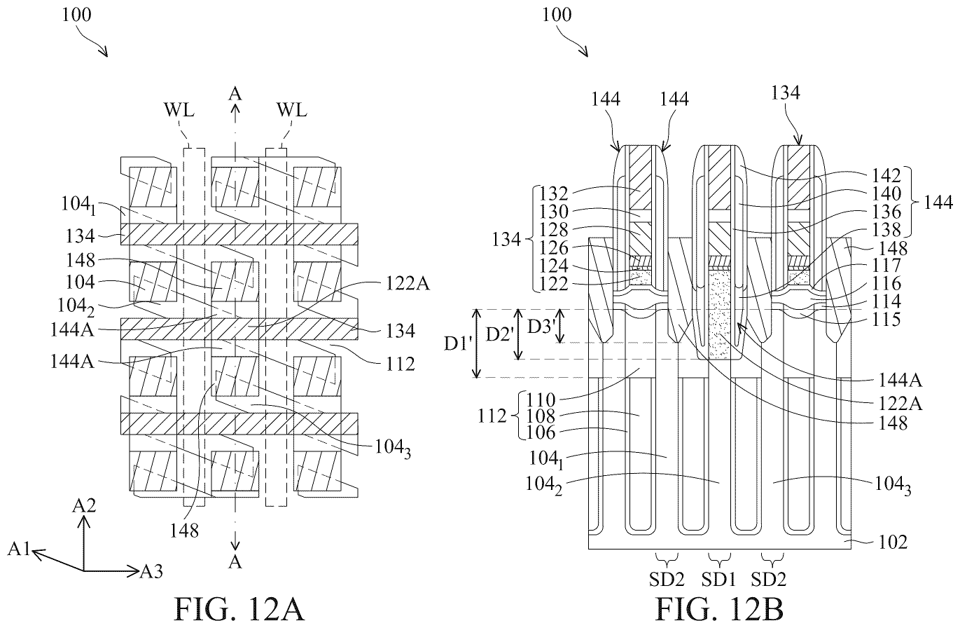

A patterning process is performed on the semiconductor memory structure 100 to form second openings 146, as shown in FIGS. 11A and 11B. Each second opening 146 corresponds to a second source/drain region SD2 and overlaps the adjacent isolation structure 112. The patterning process may include first forming a dielectric structure (not shown) directly above the word lines WL. Then, an etching process (e.g., a wet etching process or a dry etching process) is performed on the semiconductor memory structure 100 using the dielectric structure, the spacer structures 144, and the bit line structures 134 as an etching mask.

During the etching process, the second source/drain region SD2 of the active regions 104 (e.g., active regions 104₁ and 104₃ in FIG. 11B) and the adjacent second insulating material 110 are recessed to form the second openings 146, which are self-aligned with the opposite sides of the contact portions 122A (or the first openings 120 in FIG. 7A). In some embodiments, the patterning process may include a lithography process followed by an etching process.

During the etching process for forming the second openings 146, the etching rate of the second insulating material 110 is lower than that of the active regions 104. The etch selectivity of the active region 104 to the second insulating material 110 (i.e., the ratio of etching rates) is higher than the etch selectivity of the active region 104 to the first insulating material 108. In the embodiments of the present disclosure, the upper portion of the isolation structure 112 is replaced with the second insulating material 110, which has a lower etching rate. This may reduce the loss of the isolation structure 112 caused by, e.g., lateral and/or vertical recessing, during the etching process of forming the second openings 146. As a result, the conductive material subsequently formed in the second openings 146 can be prevented from being excessively close to the first source/drain regions SD1 of the adjacent active regions 104 (e.g., active region 104₂ in FIG. 11B).

FIG. 11C is an enlarged view of FIG. 11B. The etched second insulating material 110 has protruding portions 110A between the extending portions 144A of the spacer structures 144 and the second openings 146, as shown in FIG. 11C. The protruding portion 110A has an exposed surface 110S exposed from the second opening 146, with one end (top) 110S1 located on the side surface of the spacer structure 144 and the other end on the active region 104 (e.g., active regions 104₁ and 104₃). The width of the protruding portion 110A gradually increases from the top 110S1 downward. The end (top) 110S1 on the side surface of the spacer structure 144 is higher than the other end 110S2 on the surface of the active region 104. In an embodiment, the profile of the surface 110S may be linear. In other embodiments, the surface 110S may be a convex arcuate surface.

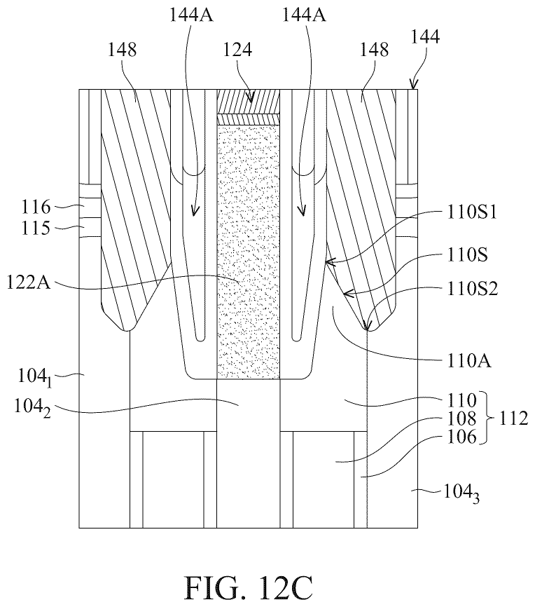

Contact plugs 148 are formed in the second openings 146, as shown in FIGS. 12A and 12B. The contact plugs 148 lands on the second source/drain regions SD2 of the active regions 104. The contact plugs 148 may be made of conductive materials such as doped or undoped polysilicon, silicide, barrier materials (e.g., titanium nitride (TiN) or tantalum nitride (TaN)), metal materials (e.g., tungsten (W), aluminum (Al), copper (Cu), cobalt (Co), or ruthenium (Ru)), and/or combinations thereof. The contact plugs 148 may be formed using a deposition process followed by an etching back process.

The bottom of the contact plug 148 is positioned higher than the bottom of the contact portion 122A. The dimension D3′, vertically measured from the top of the active region 104 to the bottom of the contact plug 148, is within a range of about 20 nm to about 35 nm. Although FIG. 12B shows that the contact plug 148 partially fills the space between the spacer structures 144, the contact plug 148 may include multiple conductive materials and fully fill the space between the spacer structures 144.

FIG. 12C is an enlarged view of FIG. 12B. Due to the better etch resistance of the second insulating material 110, the protruding portion 110A of the second insulating material 110 between the extending portion 144A of the spacer structure 144 and the contact plug 148 has a greater width. As a result, this prevents the contact plug 148 from being excessively close to the first source/drain region SD1 of the adjacent active region 104 (e.g., the active region 104₂ in FIG. 12C), thereby reducing the risk of short circuits (e.g., between the contact plug 148 and the first source/drain region SD1) in the resulting semiconductor memory device. Consequently, the manufacturing yield and reliability of the semiconductor memory device may be improved. In addition, the loss of the second insulating material 110 is relatively low during the etching processes for forming the first opening 120 and the bit line structures 134, further reducing the risk of short circuits in the resulting semiconductor memory device.

In some embodiments, the ratio (D2′/D1′) of dimension D2′ to dimension D1′ is within a range of about 0.225 to about 0.5. If the ratio (D2′/D1′) is too low, the resistance of the contact portion 122A may increase, potentially leading to the open circuit. If the ratio (D2′/D1′) is too high, the loss of the second insulating material 110 increases, which may raise a risk of the short circuit in the semiconductor memory device. In some embodiments, the ratio (D3′/D1′) of dimension D3′ to dimension D1′ is within a range of about 0.175 to about 0.4. If the ratio (D3′/D1′) is too low, the resistance of the contact plug 148 may increase, potentially leading to an open circuit. If the ratio (D3′/D1′) is too high, a risk of the short circuit in the semiconductor memory device may increase.

Additional components may be formed on the semiconductor memory structure 100 of FIGS. 11A-11C to fabricate a semiconductor memory device. For example, contact pads may be formed over the contact plugs 148, capacitor structures may be formed over the contact pads, and/or other suitable components may be formed. In some embodiments, the semiconductor memory device is a dynamic random-access memory (DRAM).

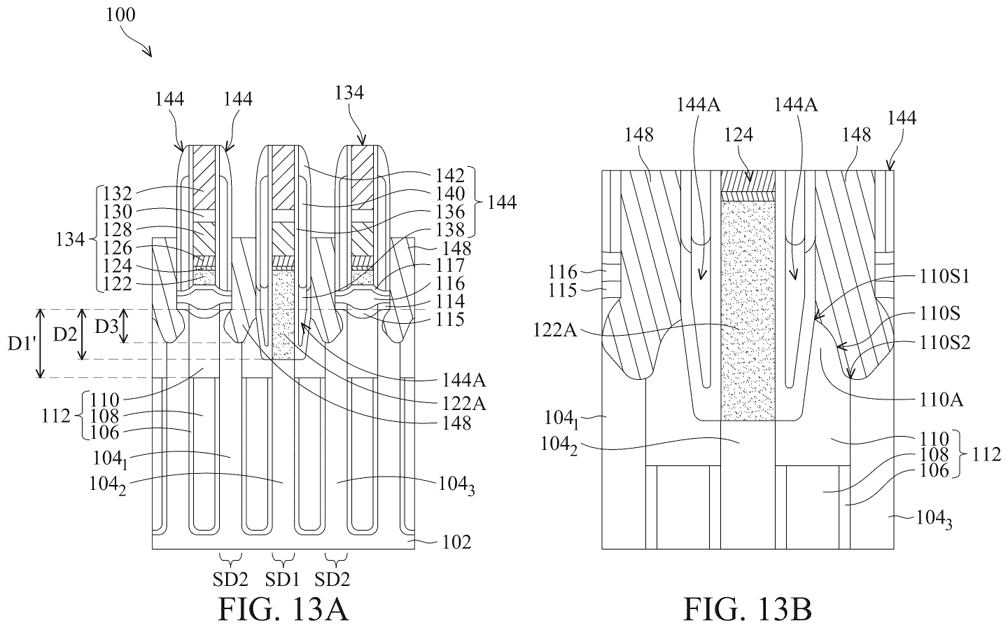

FIGS. 13A and 13B illustrate a modification of the semiconductor memory structure of FIGS. 12B and 12C. FIG. 13B is an enlarged view of FIG. 13A. The embodiments shown in FIGS. 13A and 13B are similar to the embodiments in FIGS. 1A-12C, except that the active region 104 is laterally etched.

By adjusting the etching process parameters for forming the second openings 146, the active regions 104 may be laterally etched, allowing the contact plugs 148 to extend directly under the spacer structures 144A. This increases the contact area between the contact plug 148 and the active region 104 (e.g., active regions 104₁ and 104₃ in FIG. 13B), thereby reducing the contact resistance of the contact plug 148. Furthermore, by adjusting the etching process parameters, the loss of the second insulating material 110 may be reduced, allowing the surface 110S of the protruding portion 110A of the second insulating material 110 to form a convex arcuate shape. As a result, a risk of the short circuit in the resulting semiconductor memory device may be further reduced.

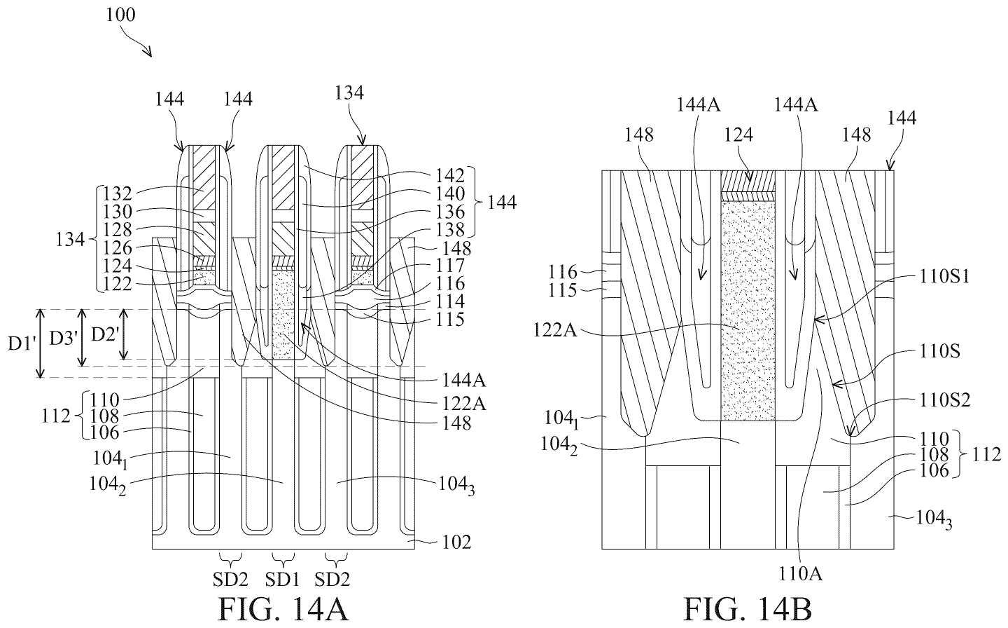

FIGS. 14A and 14B illustrate a modification of the semiconductor memory structure shown in FIGS. 12B and 12C. FIG. 14B is an enlarged view of FIG. 14A. The embodiments shown in FIGS. 14A and 14B are similar to the embodiments in FIGS. 1A-12C, except that the bottom of the contact plug 148 is positioned lower than the bottom of the contact portion 122A.

The second opening 146 may be formed to have a lower bottom than the bottom of the contact portion 122A. Due to the lower degree of lateral etching, the second opening 146 does not become excessively close to the first source/drain region SD1 of the adjacent active region 104 (e.g., active region 104₂ in FIG. 14B). The contact area between the contact plug 148 and the active region 104 (e.g., active regions 104₁ and 104₃ in FIG. 14B) may be increased, reducing the contact resistance of the contact plug 148. In other embodiments, the bottom of the contact plug 148 may be at approximately the same level as the bottom of the contact portion 122A.

As described above, in the embodiments of the present invention, the upper portion of the isolation structure is replaced with the second insulating material that has a lower etching rate, reducing the loss of the isolation structure during the etching process for forming the second opening. Consequently, the contact plug in the second opening may be prevented from being excessively close to the adjacent active region, thereby reducing a risk of the short circuit in the resulting semiconductor memory device.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor memory structure, comprising:
a first active region and a second active region adjacent to the first active region;
an isolation structure surrounding the first active region and the second active region;
a first bit line structure extending across the first active region; and
a contact plug extending into the second active region, wherein the isolation structure comprises a first insulating material and a second insulating material disposed on the first insulating material, an etch selectivity of the second active region to the second insulating material is higher than an etch selectivity of the second active region to the first insulating material, the first bit line structure comprises a contact portion extending into the first active region, and an upper surface of the first insulating material is positioned lower than a bottom of the contact portion.

2. The semiconductor memory structure as claimed in claim 1, further comprising:
a first spacer structure disposed adjacent to the first bit line structure, wherein the second insulating material comprises a protruding portion between the first spacer structure and the contact plug.

3. The semiconductor memory structure as claimed in claim 2, further comprising:
a second bit line structure extending across the second active region; and
a second spacer structure disposed adjacent to the second bit line structure, wherein the contact plug comprises a portion located directly under the second spacer structure.

4. The semiconductor memory structure as claimed in claim 2, wherein an interface between the protruding portion of the second insulating material and the contact plug has:
a first end located on a surface of the first spacer structure; and
a second end located on a surface of the second active region, wherein the first end is higher than the second end.

5. The semiconductor memory structure as claimed in claim 1, wherein:
a first dimension is a distance vertically measured from a top of the second active region to the upper surface of the first insulating material;
a second dimension is distance vertically measured from the top of the second active region to the bottom of the contact portion; and
a ratio of the second dimension to the first dimension is within a range of about 0.225 to about 0.5.

6. The semiconductor memory structure as claimed in claim 1, wherein the bottom of the contact portion is lower than a bottom of the contact plug.

7. The semiconductor memory structure as claimed in claim 1, wherein the bottom of the contact portion is higher than a bottom of the contact plug.

8. The semiconductor memory structure as claimed in claim 1, wherein the first insulating material comprises an oxide, and the second insulating material comprises a nitride.

9. The semiconductor memory structure as claimed in claim 1, wherein the isolation structure further comprises a liner surrounding the first insulating material, and the second insulating material covers a top of the liner.

10. The semiconductor memory structure as claimed in claim 1, wherein:
a first dimension is a distance vertically measured from a top of the second active region to the upper surface of the first insulating material;
a second dimension is distance vertically measured from the top of the second active region to the bottom of the contact plug; and
a ratio of the second dimension to the first dimension is within a range of about 0.175 to about 0.4.

11. A method for forming a semiconductor memory structure, comprising:
patterning a semiconductor substrate to form a first active region and a second active region;
depositing a first insulating material to surround the first active region and the second active region;
recessing the first insulating material;
depositing a second insulating material over the first insulating material to surround an upper portion of the first active region and an upper portion of the second active region;
etching the first active region and the second insulating material to form a first opening;
forming a bit line structure extending across the first active region and partially filling the first opening;
etching the second active region and the second insulating material to form a second opening; and
depositing a conductive material into the second opening.

12. The method for forming the semiconductor memory structure as claimed in claim 11, wherein the second insulating material has an etching selectivity different from an etching selectivity of the first insulating material.

13. The method for forming the semiconductor memory structure as claimed in claim 11, wherein:
each of the first active region and the second active region is a semiconductor island extending in a first horizontal direction,
each of the first active region and the second active region comprises a first source/drain region located at a central portion of the semiconductor island, a second source/drain region located at one end of the semiconductor island, and a channel region between the first source/drain region and the second source/drain region,
in a top view, the first opening overlaps the first source/drain region of the first active region, and
in the top view, the second opening overlaps the second source/drain region of the second active region.

14. The method for forming the semiconductor memory structure as claimed in claim 13, further comprising:
forming a word line through the channel region of the first active region and extending along a second horizontal direction, wherein the second horizontal direction is neither perpendicular nor parallel to the first direction.

15. The method for forming the semiconductor memory structure as claimed in claim 11, further comprising:
forming a first spacer structure alongside the bit line structure to fill a remaining portion of the first opening.

16. The method for forming the semiconductor memory structure as claimed in claim 15, wherein the second active region and the second insulating material are etched so that the second insulating material includes a protruding portion between the first spacer structure and the second opening, and a width of the protruding portion increases downward.

17. The method for forming the semiconductor memory structure as claimed in claim 16, wherein the protruding portion of the second insulating material has an exposed surface from the second opening, and the exposed surface is a convex arcuate surface.

18. The method for forming the semiconductor memory structure as claimed in claim 11, wherein a bottom of the first opening is higher than an interface between the first insulating material and the second insulating material.

19. The method for forming the semiconductor memory structure as claimed in claim 11, further comprising:
forming a liner along the first active region and the second active region, wherein the first insulating material is deposited over the liner; and
recessing the liner to expose the upper portion of the first active region and the upper portion of the second active region.

20. The method for forming the semiconductor memory structure as claimed in claim 11, wherein the bit line structure includes a polysilicon layer, a silicide layer on the polysilicon layer and a metal layer on the silicide layer.
